(19) United States
(12) Patent Application Publication
(10) Pub. No.: US 2009/0250700 A1
(43) Pub. Date: Oct. 8, 2009

(54) Crystalline Semiconductor Stripe Transistor

(76) Inventors: Themistokles Afentakis, Vancouver, WA (US); Robert S. Sposili, Vancouver, WA (US); Apostolos T. Voutsas, Portland, OR (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(21) Appl. No.: 12/099,756

(22) Filed: Apr. 8, 2008

(51) Int. Cl. H01L 29/786; H01L 21/336; H01L 29/76

(52) U.S. Cl. 257/66; 438/166; 257/347; 257/E29.273; 257/E21.411; 257/401

(57) ABSTRACT

A transistor with crystalline semiconductor stripes and an associated fabrication process are provided. The method provides a substrate, and deposits a semiconductor layer overlying the substrate. The semiconductor layer is irradiated using a scanning step-and-repeat laser annealing process, which agglomerates portions of the semiconductor layer. In response to cooling agglomerated semiconductor material, a transistor active semiconductor region is formed including a plurality of crystalline semiconductor stripes oriented along parallel axes. In one aspect, a channel region is formed from the plurality of oriented crystalline semiconductor stripes, and the method forms a gate dielectric overlying the channel region, with a gate electrode overlying the gate dielectric. In another aspect, forming the transistor active semiconductor region includes forming source, drain, and channel regions from the plurality of oriented crystalline semiconductor stripes.

### RELATED APPLICATIONS

This application is related to a pending application entitled, CRYSTALLINE SEMICONDUCTOR STRIPES, invented by Afentakis et al., Ser. No. ______, filed ______, Attorney Docket No. SLA2206, which is incorporated herein by reference.

### BACKGROUND OF THE INVENTION

1. Field of the Invention

This invention generally relates to integrated circuit (IC) fabrication and, more particularly, to crystalline semiconductor stripe transistor and an associated fabrication process.

2. Description of the Related Art

The benefits of low-defect-density active silicon films are well known for use in thin film transistors (TFTs). High crystallinity silicon has a higher mobility and steeper subthreshold slope, while device uniformity and reliability also improves. Thin film transistors are usually employed in display applications, where, among other processing constraints, there is a need for a reduced thermal budget due to the properties of the glass substrate. These two requirements, i.e., low defect density and low thermal budget, have made laser crystallization the prominent approach for fabricating high-performance thin-film transistors from polycrystalline or amorphous Si active films.

The conventional laser annealing processes for Si crystallization/recrystallization are not without problems, however. The resulting polycrystalline structure has a typically higher surface roughness than the initial, as-deposited film, and areas of high defect density exist between grains (grain boundaries). Therefore, the TFT effective mobility can suffer from surface scattering and interface/bulk trapping effects. The device uniformity and most importantly, mobility deviation around the mean, can be much higher than either amorphous Si or single-crystal Si transistors.

Crystal structure and device property uniformity are addressed by a number of variations of the laser crystallization process, falling into two basic categories: a) laser beam and scanning strategy engineering (beam profile shaping, sequential scanning & overlapping techniques, etc.); and, b) active film structure engineering (antireflective coat deposition and patterning, etc.)

In this group of optimization variables, laser energy and beam profile are crucial in order to obtain the best crystal structure, i.e., repeatable large grains. Extreme laser energies, either too high or too low are undesirable because they lead to very fine grains (the result of copious film nucleation) or agglomeration (which breaks film continuity). For a static, flood-irradiation scheme, the energy window associated with the largest grains is very narrow and strongly correlated with film thickness. Since inevitable process variations can cause large variations in film quality, if energy is confined to this narrow range, a sub-optimal range or overlapping scanning techniques (such as sequential lateral solidification) are employed for increased robustness.

FIGS. 1A through 1C are perspective views depicting steps in a conventional laser annealing process (prior art). The process typically begins with a glass or quartz substrate, onto which one or several insulating basecoat layers are deposited (FIG. 1A). Amorphous or polycrystalline Si is then deposited, commonly with a chemical vapor deposition (CVD) process (FIG. 1B). After laser crystallization, the film retains its mean thickness, but typically the surface roughness has increased. However, the crystal structure of the film has improved significantly over the as-deposited film (FIG. 1C).

Typically, excimer lasers emitting in the UV range are used to anneal amorphous or polycrystalline silicon precursor films. Silicon has a strong absorption of UV radiation and a short diffusion length, resulting in a high energy transfer to the film. In this process, temperatures at the surface of the film exceed the melting point of silicon, while the substrate is not appreciably heated, making to possible to keep the transparent substrate at temperature below 400° C.

The resulting crystal structure of the semiconductor film is largely dependent on the laser pulse energy. Three main regions of crystal growth have been identified: at low energies, the resulting film is composed of a fine-grained bottom layer and a larger grain upper layer generated by vertical solidification. At medium energies, the entirety of the film is melted except a few dispersed crystalline clusters. These clusters are acting as seeds for the lateral growth of crystalline grain as the film cools down. Grain boundaries form when the solidification fronts impinge on each other. Large grains and high electron mobility films are obtained using this process. At high energies, complete melting is induced, resulting in small grains and low carrier mobility. Beyond this region, the film agglomerates from the surface, creating voids and discontinuities. Thus, for the purpose of obtaining high quality devices, low and high energy regions have been, by default, discarded. However, the correct processing window for excimer laser annealing (ELA) is very narrow, because of the steep dependence of polysilicon grain size on laser energy. Consequently, laser systems with very high illumination uniformity and very low pulse-to-pulse fluctuation are required.

It would be advantageous if semiconductor crystalline structures could be formed for use in TFTs with a decreased surface roughness, as compared to the product of conventional laser annealing processes.

It would be advantageous if semiconductor crystalline structures could be formed for use in TFTs that were less susceptible to process variations.

### SUMMARY OF THE INVENTION

The present invention uses a laser beam and scanning strategy engineering technique to form crystallized semiconductor stripes oriented in a controlled shape. The crystallized semiconductor stripes can be used in the fabrication of a thin film transistor structure whose active region is Si agglomerated through laser annealing. In contrast to conventional laser annealing processes, the claimed invention can be used to form tapered agglomerated Si island sidewalls, resulting in more uniform gate insulator and gate electrode coverage, and minimizing high electric field points that are usually present around the corners. Further, the surface roughness of the agglomerated islands is lower, resulting in a lower defect density.

Although film agglomeration has been thought to be very undesirable in excimer laser annealing (ELA), under certain conditions uniform “ribbon” or stripe-shaped structures result. This type of self-forming agglomerated topography, which typically approximates a half-cylindrical shape, is found to possess two very desirable properties not found in typical ELA films. First, there are no steep angles in the channel cross-section, where high field and gate oxide step-coverage related problems originate. Second, the crystal structure of these stripes can be made almost single-crystal, with little or no grain boundaries over distances of tens of microns, as verified with electron back-scattering diffraction (EBSD) scans.

Accordingly, a method is provided for fabricating a transistor with oriented crystalline semiconductor stripes. The method provides a substrate, and deposits a semiconductor layer overlying the substrate. The semiconductor layer is irradiated using a scanning step-and-repeat laser annealing process, which agglomerates portions of the semiconductor layer. In response to cooling agglomerated semiconductor material, a transistor active semiconductor region is formed including a plurality of crystalline semiconductor stripes oriented along parallel axes.

In one aspect, a channel region is formed from the plurality of oriented crystalline semiconductor stripes, and the method forms a gate dielectric overlying the channel region, with a gate electrode overlying the gate dielectric. In another aspect, forming the transistor active semiconductor region includes forming source, drain, and channel regions from the plurality of oriented crystalline semiconductor stripes.

Typically, each crystalline semiconductor stripe is aligned approximately with a straight line axis overlying a top surface of the substrate. In some aspects, a surface feature is formed in the top surface of the substrate, and crystalline semiconductor stripes are oriented in an axis that is in alignment with the surface feature. Each crystalline semiconductor stripe may include a plurality of consecutive ring segments circumscribing the stripe axis. The ring segments have a width about equal to the laser annealing process step distance.

Additional details of the above-described method and a transistor with oriented crystalline semiconductor stripes are provided below.

### BRIEF DESCRIPTION OF THE DRAWINGS

FIGS. 1A through 1C are perspective views depicting steps in a conventional laser annealing process (prior art).

FIG. 2A is a plan view and FIGS. 2B and 2C are partial cross-sectional views of an oriented crystalline semiconductor stripe structure.

FIGS. 3A through 3C are partial cross-sectional views depicting a first variation of the crystalline semiconductor stripe of FIGS. 2A-2C.

FIGS. 4A and 4B are plan and partial cross-sectional views, respectively, depicting a second variation of the crystalline semiconductor stripe of FIGS. 2A-2C.

FIGS. 5A and 5B are plan and partial cross-sectional views, respectively, of a transistor with oriented crystalline semiconductor stripes.

FIGS. 6A and 6B are, respectively, a scanning electron microscope (SEM) photo of agglomerated Si film after laser irradiation, and an atomic force microscope (AFM) scan of same area.

FIGS. 7A through 7L are plan views depicting steps in a process of fabricating a TFT with a crystallized semiconductor stripe active layer.

FIGS. 8A through 8D are optical microscope image representations showing the TFT during device fabrication steps.

FIG. 9 is an I_{D}-V_{G} plot summarizing the results of 60 NMOS (fine cross-hatch) and 60 PMOS TFTs (coarse cross-hatch) at |V_{D}|=100 mV made using a crystallized stripe active layer.

FIGS. 10A and 10B are, respectively, high-resolution I_{D}-V_{G} and I_{D}-V_{D} curves of a typical L=2 μm NMOS whose active region is comprised of two parallel Si stripes.

FIG. 11 is a flowchart illustrating a method for fabricating a TFT with oriented crystalline semiconductor stripes.

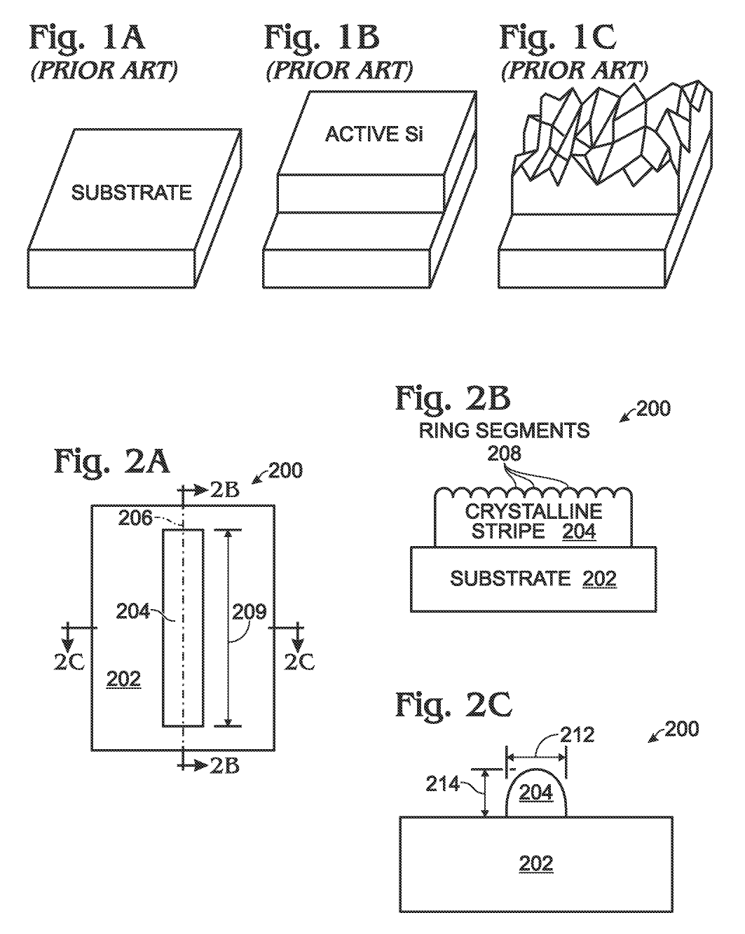

### DETAILED DESCRIPTION

FIG. 2A is a plan view and FIGS. 2B and 2C are partial cross-sectional views of an oriented crystalline semiconductor stripe structure. The crystalline semiconductor stripes are referred to as “oriented” in that the stripes are generally aligned in a controlled manner with the direction of laser scanned used in fabrication. The crystalline semiconductor stripe structure 200 comprises a substrate 202. A crystallized semiconductor material has a stripe shape 204 that is aligned with an axis 206 (as seen from above in the plan view) overlying the substrate 202. In one aspect, the axis 206 is a straight line (as shown in FIG. 2A). The crystallized stripe 204 has a plurality of sequential ring segments 208 circumscribing the axis 206.

In one particular aspect, starting with an initial silicon film thickness of 50 nanometers and irradiating with laser energies in the range of 600 and 640 milli-Joules per square centimeter (mJ/cm²), the crystallized stripe 204 has a length 209 in the range of about 10 micrometers to 10 centimeters, a width 212 of about 2.4 micrometers, and a height 214 of about 260 nanometers. In one aspect, the crystalline semiconductor stripe 204 has a top surface shape 210 of a truncated cylinder (FIG. 2C) or a parabolic cross section (not shown), such top surface shapes alternatively being described herein as selected from a group consisting of a truncated cylinder or a parabolic cross-section.

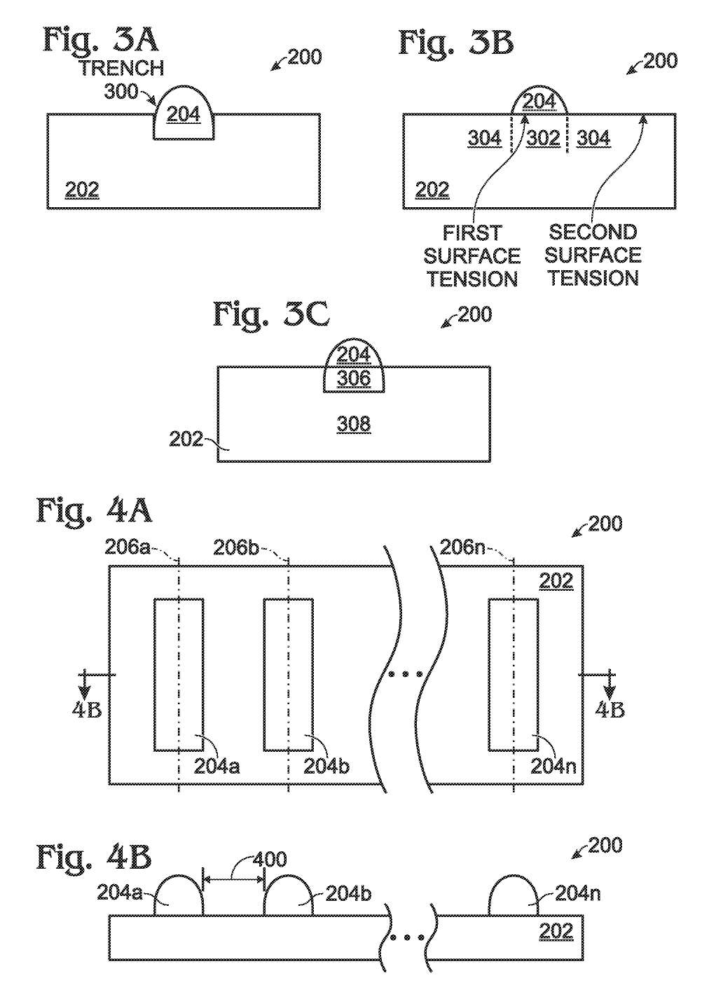

FIGS. 3A through 3C are partial cross-sectional views depicting a first variation of the crystalline semiconductor stripe of FIGS. 2A-2C. In this aspect the substrate 202 has a surface feature, and the crystalline semiconductor stripe axis 206 is aligned with the surface feature. In FIG. 3A the surface feature is a trench 300. In FIG. 3B the surface feature is a region with a first surface tension 302 formed in an insulator substrate 202 having an overall second surface tension 304. In FIG. 3C the surface feature is a region of a first material 306 formed in a substrate 202 made from an overall second material 308. In one aspect not shown, the surface feature may have a curved shape (as seen from above) and the stripe follows the surface feature, even if the surface feature direction varies from the direction of laser scanning.

FIGS. 4A and 4B are plan and partial cross-sectional views, respectively, depicting a second variation of the crystalline semiconductor stripe of FIGS. 2A-2C. This aspect comprises a plurality of crystalline stripes 204a through 204n, where n is not limited to any particular value. The crystalline stripes are oriented with a corresponding plurality of parallel axes 206a through 206n, with a pitch 400 between stripes that depends primarily on the initial semiconductor film thickness and the substrate material. In one particular aspect, for a 50 nanometer-thick silicon film on a silicon dioxide substrate, the pitch 400 between stripes is about 11 micrometers.

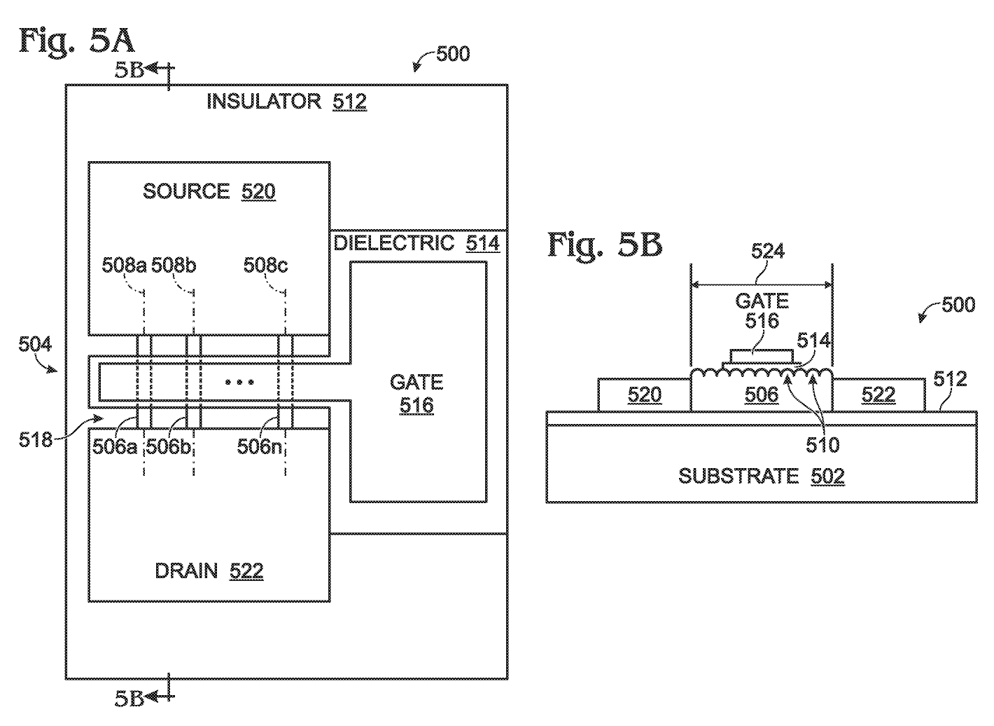

FIGS. 5A and 5B are plan and partial cross-sectional views, respectively, of a transistor with oriented crystalline semiconductor stripes. The transistor 500 comprises a substrate 502. For example, the substrate 500 may be a transparent materials such a glass, quartz, or plastic, or a semiconductor material. A transistor active semiconductor region 504 includes a plurality of crystallized semiconductor material stripe shapes 506a through 506n, where n is not limited to any particular value. The stripes 506 are oriented with corresponding parallel axes 508a through 508n overlying the substrate 502. Each stripe 506 includes a plurality of sequential ring segments 510 circumscribing its axis 506. The crystallized stripes 506 have either a single-crystal or polycrystalline structure and are typically a material such as Si, Ge, or SiGe.

Typically (as shown), an insulator layer or basecoat 512 overlies the substrate 502. The insulator layer 512 may be an oxide, nitride, or ceramic for example. In one aspect, the insulator layer 512 is either an oxide or a nitride, and includes a first material. Then, the crystallized stripes 506 also include the first material. For example, the insulator layer 512 may be silicon dioxide and the crystalline stripes 506 may be silicon. Typically (as shown), each crystallized strip 506 has an axis 508 oriented as a straight line across the substrate (insulator) top surface 513.

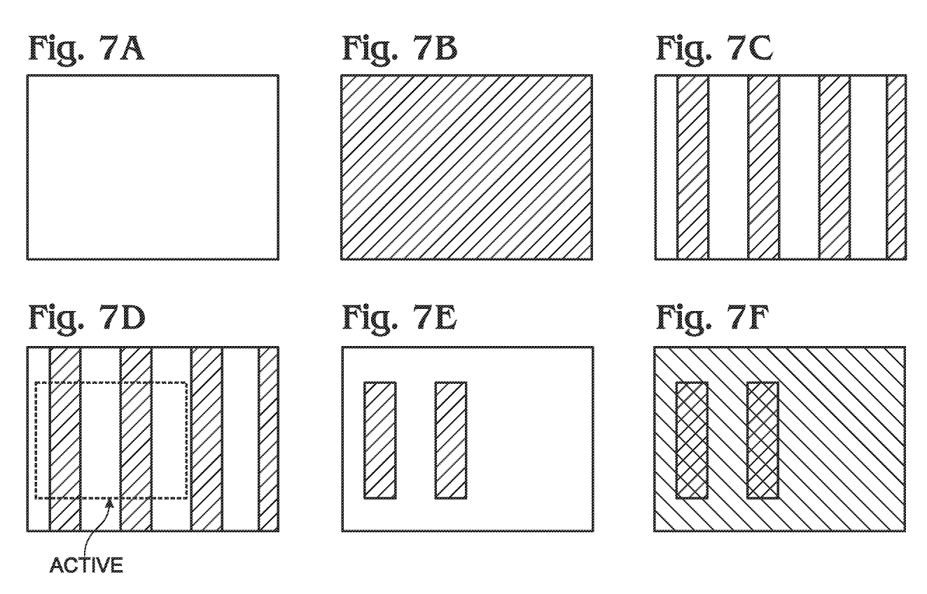

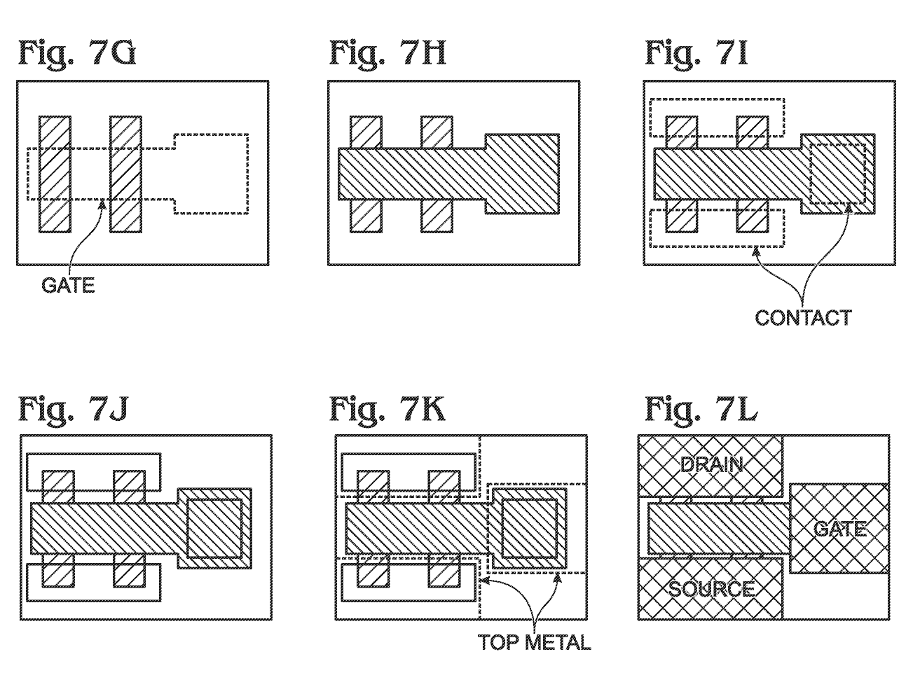

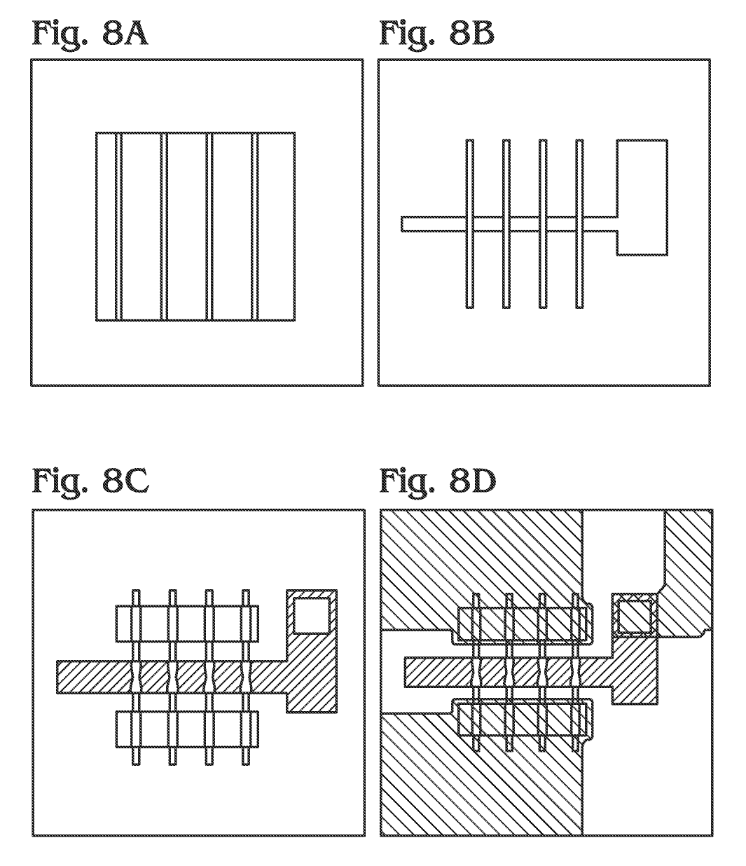

A gate dielectric 514 overlies the active semiconductor region 504 and a gate electrode 516 overlies the gate dielectric 514. In one aspect as shown, the transistor active semiconductor region 504 includes a channel region 518 formed from the plurality of oriented crystalline semiconductor stripes 506a-506n. That is, only the semiconductor in the channel region is agglomerated. Alternately, as shown in FIGS. 7L and 8D, the transistor active semiconductor region 504 includes source 520, drain 522, and channel 518 regions formed, at least partially from the plurality of oriented crystalline semiconductor stripes 506a-506n. Typically, each crystallized stripe 506 has a length 524 in the range of about 10 micrometers to 10 centimeters.

As noted above, the crystallized stripes may have a top surface shape approximating either a truncated cylinder or a parabolic cross section, see FIG. 2C. In another aspect, the substrate has a surface feature and the crystallized stripes have axes aligned with the substrate surface feature, see FIGS. 3A-3C. The stripe widths, heights, and pitch described above in the explanations of FIGS. 2A-2C, 3A-3C, and 4A-4B are applicable to the stripes of FIGS. 5A and 5B.

### Functional Description

The fabrication sequence needed to produce the desired crystallized semiconductor stripes for use as an active film is dependent on the deposited semiconductor film thickness. Table 1 describes laser irradiation conditions for a 50 nm thick Si film deposited on a quartz substrate via plasma-enhanced chemical vapor deposition (PECVD), followed by dehydrogenation in a nitrogen ambient furnace at 500° C., and finally by laser annealing. The various laser conditions are applied to sample 0.5 mm×0.5 mm areas. The number of shots per area equals the ratio of slit width over step size. The experiment results are labeled “A” (periodic parallel stripes), “B” (agglomeration occurring with various non-periodic discontinuities), and “X” (no agglomeration observed). Only result “A” produces a desirable parallel stripe structure.

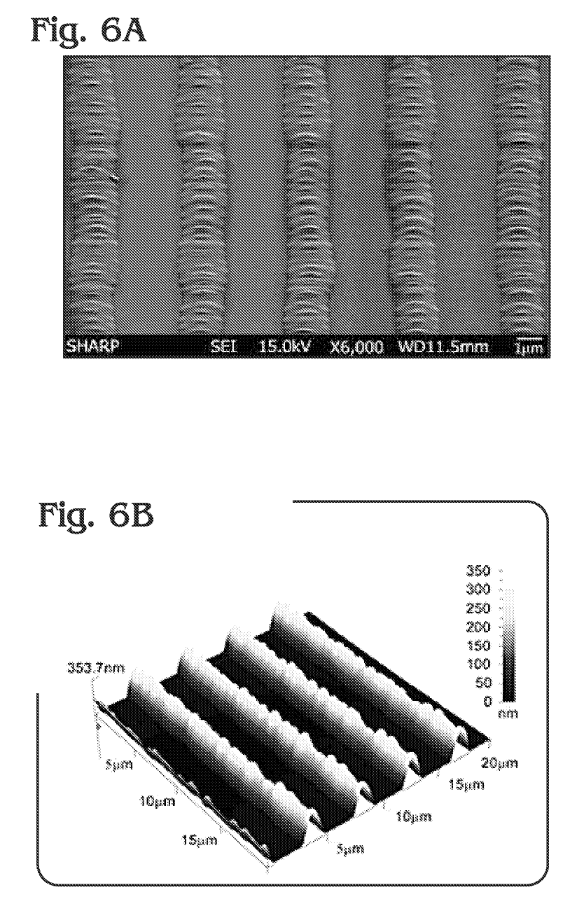

FIGS. 6A and 6B are, respectively, a scanning electron microscope (SEM) photo of agglomerated Si film after laser irradiation,

TABLE 1
Excimer laser irradiation conditions in silicon agglomeration experiment

| Slit width | Step size | No. of | Laser fluence (mJ/cm²) | | | | | | | | | | |
|---|---|---|---|---|---|---|---|---|---|---|---|---|---|
| (μm) | (μm) | Shots | 530 | 559 | 586 | 601 | 616 | 626 | 632 | 635 | 636 | 636 | 637 |
| 4 | 0.1 | 40 | X | X | X | A | A | A | A | A | A | A | A |
| 4 | 0.25 | 16 | X | X | X | X | X | B | B | B | B | B | B |
| 4 | 0.5 | 8 | X | X | X | X | B | B | B | B | B | B | B |
| 4 | 1 | 4 | X | X | X | X | X | X | X | X | X | X | X |
| 6 | 0.1 | 60 | X | X | X | X | X | X | X | A | A | A | A |
| 6 | 0.25 | 24 | X | X | X | X | B | B | B | B | B | B | B |

and an atomic force microscope (AFM) scan of same area. Atomic force microscope and scanning electron microscope pictures are shown for crystallized Si stripes fabricated using a slit width=4 μm, step=0.1 Mm, and fluence=636 mJ/cm².

One exemplary TFT fabrication process is as follows: After cleaning the substrate, a 300-nm-thick layer of TEOS SiO₂ base coat is deposited with plasma-enhanced chemical vapor deposition (PECVD), and then furnace annealed. The active film is deposited, dehydrogenated, and laser-annealed as described in the previous paragraph. A TEOS SiO₂ gate insulator is then PECVD deposited, 50 nm thick, followed by the Si gate electrode, 200 nm thick. The Si gate is ion implanted n+ or p+, for NMOS or PMOS TFTs, respectively. After patterning the gate, the drain/source regions are ion-implanted. For 250-nm-thick Si stripes (the Si layer deposited to form the stripes is 250 nm thick), the conditions are Phosphorus, 3×10¹⁵ ions/cm², 80 keV or Boron, 5×10¹⁵ ions/cm², 35 keV. The dopants are then activated in the furnace. Then, the passivation oxide (TEOS) is PECVD deposited, 300 nm thick, followed by contact hole patterning and etching, and metal deposition. The metal is a standard Ti/TiN/Al stack. A typical post-processing step is plasma hydrogenation. The TFTs are hydrogenated for 10 minutes.

FIGS. 7A through 7L are plan views depicting steps in a process of fabricating a TFT with a crystallized semiconductor stripe active layer. The process begins with a transparent substrate (FIG. 7A), onto which the amorphous or polycrystalline Si precursor Si film is deposited (FIG. 7B). After excimer laser irradiation, the desired “stripe” structure forms spontaneously (FIG. 7C). The active layer is patterned (FIG. 7D), etching the active Si film and leaving stripes (FIG. 7E). The gate oxide is then deposited (FIG. 7F), followed by the deposition of the gate Si layer (FIG. 7G). Alternately, the gate material can be a suitable metal. If necessary, the gate layer receives degenerative doping for metal-like electrical properties. The gate film is patterned with the gate layer, which etches the gate Si and forms the gate electrode (FIG. 7H).

Then, a thick passivation film, typically silicon dioxide, is deposited, and the contact holes, intended for contact to the gate electrode and the active drain/source TFT regions, are defined (FIG. 7I). The passivation oxide is etched in the contact hole area (FIG. 7J). The top metal is then deposited, as a single film or a stack (FIG. 7K), and the metal regions are defined. Finally, the top metal is etched (FIG. 7L), providing contact to the TFT terminals and interconnects with other devices (not shown).

FIGS. 8A through 8D are optical microscope image representations showing the TFT during device fabrication steps. This device's active region is comprised of four parallel Si stripes. FIG. 8A is an image after active layer patterning. The photoresist block is present. FIG. 8B is an image after gate electrode patterning. FIG. 8C is an image after contact hole etching, and FIG. 8D is an image of the finished device after top metal patterning.

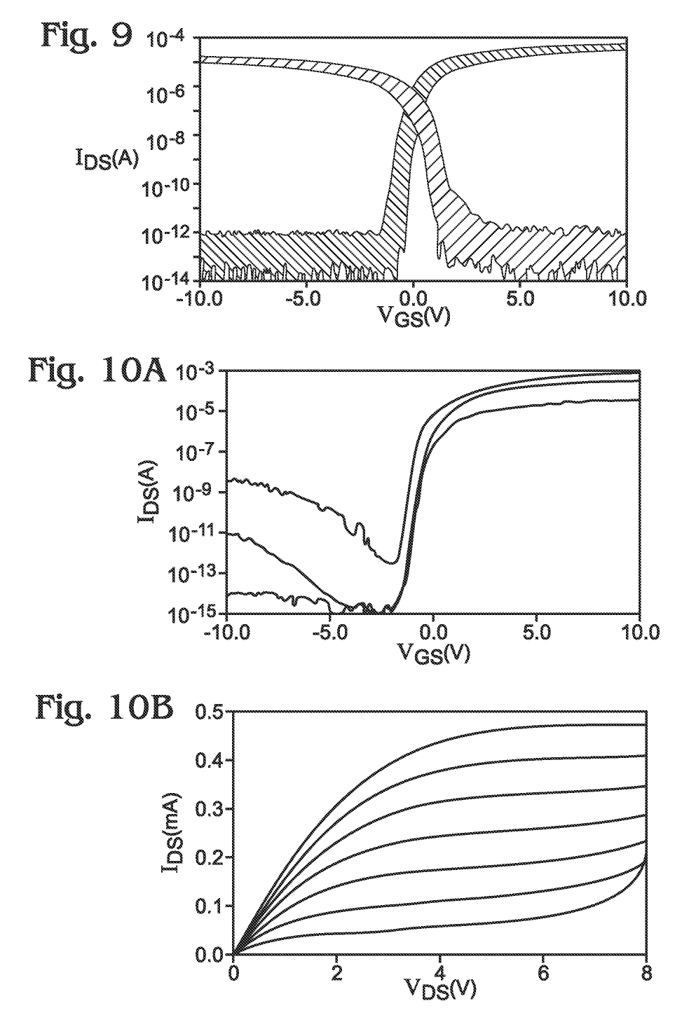

FIG. 9 is an I_{D}-V_{G} plot summarizing the results of 60 NMOS (fine cross-hatch) and 60 PMOS TFTs (coarse cross-hatch) at |V_{D}|=100 mV made using a crystallized stripe active layer. Each transistor's active region is comprised of two parallel Si stripes. The TFTs were fabricated with two stripes per active layer. The channel width used for the effective mobility calculation is the average “stripe” surface width obtained from AFM measurements (about 3.55 μm) multiplied by the number of Si sections in the device. The nominal channel length is 2 μm, at |V_{D}|=100 mV. The W/L ratio is assumed to be 7.1/2. Threshold voltage, effective mobility and inverse subthreshold slope statistics are shown in Table 2.

TABLE 2
Mean electrical parameters of fabricated TFTs

| | | Inverse | |
|---|---|---|---|
| | Threshold | Subthreshold | Effective |
| | Voltage | Slope | Mobility |
| | (V) | (mV/decade) | (cm²/Vs) |
| NMOS | +0.406 | 196 | 257.6 |
| PMOS | −0.469 | 276 | 54.6 |

FIGS. 10A and 10B are, respectively, high-resolution I_{D}-V_{G} and I_{D}-V_{D} curves of a typical L=2 μm NMOS whose active region is comprised of two parallel Si stripes. FIG. 10A is an I_{D}-V_{G} plot of a two-stripe NMOS with L=2 μm at V_{D}=0.1, 1, and 5V. This is a high resolution, large integration time measurement. Hence, the leakage current is lower than what shown in FIG. 9. FIG. 10B depicts I_{D}-V_{D} curves of the same TFT at a V_{G} ranging from 2 to 8 V, in 1 V steps. Parameters extracted from the linear I_{D}-V_{c} plots (|V_{D}|=100 mV) include minimum subthreshold slopes measured at 133 mV/dec (NMOS) and 179 mV/dec (PMOS). Maximum mobility is 360.0 cm²/Vs (NMOS) and 72.9 cm²/Vs (PMOS).

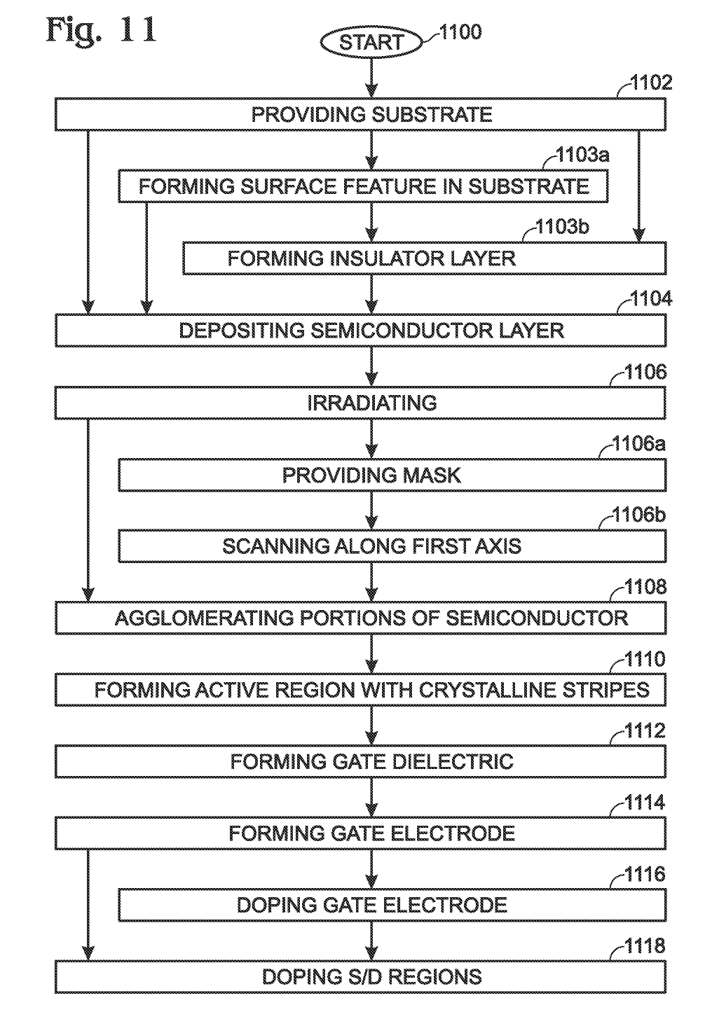

FIG. 11 is a flowchart illustrating a method for fabricating a TFT with oriented crystalline semiconductor stripes. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 1100.

Step 1100 provides a substrate. The substrate can be a semiconductor or transparent material. In some aspects, Step 1103b forms an insulator layer of oxide, nitride, or ceramic. Step 1104 deposits a semiconductor layer overlying the substrate (and optional insulator). Typically, the semiconductor is Si, Ge, or SiGe. Step 1106 irradiates the semiconductor layer using a scanning step-and-repeat laser annealing process. Step 1108 agglomerates portions of the semiconductor layer. In response to cooling agglomerated semiconductor material, Step 1110 forms a transistor active semiconductor region including a plurality of crystalline semiconductor stripes oriented along parallel axes. The crystalline semiconductor stripes formed in Step 1110 have a shape responsive to the scanning rate, step distance, pulse duration, and energy density of the laser annealing process (Step 1106).

In one aspect, forming the transistor active semiconductor region in Step 1110 includes forming a channel region from the plurality of oriented crystalline semiconductor stripes. Alternately, Step 1110 forms channel, source, and drain regions from the plurality of oriented crystalline semiconductor stripes. Then, Step 1112 forms a gate dielectric overlying the channel region, and Step 1114 forms a gate electrode overlying the gate dielectric. In another aspect, Step 1116 dopes the gate electrode, for example, if the gate electrode is a semiconductor material. Step 1118 dopes source and drain (S/D) regions in the transistor active semiconductor region.

In one aspect, forming oriented crystalline semiconductor stripes on the insulator substrate in Step 1110 includes forming oriented crystalline semiconductor stripes having a length in the range of about 10 micrometers to 10 centimeters. In another aspect, Step 1110 forms crystalline semiconductor stripes aligned approximately with a straight line stripe axis overlying a top surface of the insulating substrate. In a different aspect, Step 1110 forms each crystalline semiconductor stripe with a plurality of consecutive ring segments circumscribing the stripe axis. Typically, the ring segments have a width about equal to the laser annealing process step distance. The step distance is the amount traveled by the laser annealing mask (or substrate) in each “step” of the step-and-repeat laser annealing process. In another aspect, Step 1110 forms crystalline semiconductor stripes having a top surface shape approximating either a truncated cylinder or a parabolic cross-section. The crystalline semiconductor stripes typically have either a single-crystal or polycrystalline structure.

In one aspect, Step 1103a forms a surface feature in a top surface of the substrate. The surface feature may be a trench, a region with a first surface tension formed in a substrate having an overall second surface tension, or a region of a first material formed in a substrate made from an overall second material. Then, forming oriented crystalline semiconductor stripes on the insulator substrate in Step 1110 includes forming crystalline semiconductor stripes oriented with an axis aligned with the surface feature.

In another aspect, irradiating the semiconductor layer using the scanning step-and-repeat laser annealing process in Step 1106 includes substeps. Step 1106a provides a mask with a plurality of parallel apertures. Step 1106b scans through the mask along a first axis overlying a top surface of the substrate. Then, forming oriented crystalline semiconductor stripes on the substrate in Step 1110 includes forming crystalline semiconductor stripes oriented in parallel to the first axis.

In one aspect, providing the insulator layer in Step 1103b includes providing either an oxide or nitride substrate that further includes a first material. Then, depositing the semiconductor layer in Step 1104 includes depositing a semiconductor including the first material.

For example, depositing the semiconductor layer overlying the insulator substrate in Step 1104 may include depositing a 50 nanometer Si precursor film overlying a Si dioxide substrate. Then, forming oriented crystalline semiconductor stripes in Step 1110 includes forming crystalline Si stripes having a width of about 2.4 micrometers, a pitch between stripes of about 11 micrometers, and a height of about 260 nanometers.

A TFT fabricated with crystalline semiconductor stripes and an associated fabrication process have been provided. Details of particular structures, materials, and processes have been given to illustrate the invention. However, the invention is not limited to merely these examples. Other variations and embodiments of the invention will occur to those skilled in the art.

We claim:

1. A method for fabricating a transistor with oriented crystalline semiconductor stripes, the method comprising:
providing a substrate;
depositing a semiconductor layer overlying the substrate;
irradiating the semiconductor layer using a scanning step-and-repeat laser annealing process;
agglomerating portions of the semiconductor layer; and,
in response to cooling agglomerated semiconductor material, forming a transistor active semiconductor region including a plurality of crystalline semiconductor stripes oriented along parallel axes.

2. The method of claim 1 wherein forming the transistor active semiconductor region includes forming a channel region from the plurality of oriented crystalline semiconductor stripes; and,
the method further comprising:
forming a gate dielectric overlying the channel region; and,
forming a gate electrode overlying the gate dielectric.

3. The method of claim 1 wherein forming the transistor active semiconductor region includes forming channel, source, and drain regions from the plurality of oriented crystalline semiconductor stripes; and,
the method further comprising:
forming a gate dielectric overlying the channel region; and,
forming a gate electrode overlying the gate dielectric.

4. The method of claim 3 further comprising:
doping the gate electrode;
doping source and drain regions in the transistor active semiconductor region.

5. The method of claim 1 wherein forming the transistor active semiconductor region includes forming oriented crystalline semiconductor stripes having a length in a range of about 10 micrometers to 10 centimeters.

6. The method of claim 1 wherein forming the transistor active semiconductor region includes forming each crystalline semiconductor stripe aligned approximately with a straight line axis overlying a top surface of the substrate.

7. The method of claim 1 wherein forming the transistor active semiconductor region includes forming oriented crystalline semiconductor stripes having a top surface shape selected from a group consisting of a truncated cylinder and a parabolic cross section.

8. The method of claim 1 wherein forming the transistor active semiconductor region includes forming each crystalline semiconductor stripe comprising a plurality of consecutive ring segments circumscribing the stripe axis.

9. The method of claim 8 wherein forming consecutive ring segments includes forming rings segments have a width about equal to the laser annealing process step distance.

10. The method of claim 1 further comprising:
forming a surface feature in a top surface of the substrate: and,
wherein forming the transistor active semiconductor region includes forming crystalline semiconductor stripes having axes aligned with the surface feature.

11. The method of claim 10 wherein forming the surface feature in the top surface of the substrate includes forming a surface feature selected from a group consisting of a trench, a region with a first surface tension formed in a substrate having an overall second surface tension, and a region of a first material formed in a substrate made from an overall second material.

12. The method of claim 1 wherein forming the transistor active semiconductor region includes forming crystalline semiconductor stripes having a crystalline structure selected from a group consisting of single-crystal and polycrystalline.

13. The method of claim 1 wherein irradiating the semiconductor layer using the scanning step-and-repeat laser annealing process includes:
providing a mask with a plurality of parallel apertures; and,
scanning through the mask along a first axis overlying a top surface of the substrate; and,
wherein forming the transistor active semiconductor region includes forming crystalline semiconductor stripes oriented in parallel with the first axis.

14. The method of claim 1 further comprising:
depositing an insulator layer overlying the substrate made from a material selected from a group consisting of an oxide and a nitride, and including a first material; and,
wherein depositing the semiconductor layer includes depositing a semiconductor including the first material.

15. A transistor with oriented crystalline semiconductor stripes, the transistor comprising:
a substrate;
a transistor active semiconductor region including a plurality of crystallized semiconductor material stripe shapes oriented with parallel axes overlying the substrate, where each stripe includes a plurality of sequential ring segments circumscribing its axis;
a gate dielectric overlying the active semiconductor region; and,
a gate electrode overlying the gate dielectric.

16. The transistor of claim 15 wherein each crystallized stripe has a length in a range of about 10 micrometers to 10 centimeters.

17. The transistor of claim 15 wherein the substrate has a top surface; and,
wherein each crystallized strip has an axis oriented as a straight line across the substrate top surface.

18. The transistor of claim 15 wherein the crystallized stripes have a top surface shape selected from a group consisting of a truncated cylinder and a parabolic cross section.

19. The transistor of claim 15 wherein the substrate has a surface feature; and,
wherein the crystallized stripes have axes aligned with the substrate surface feature.

20. The transistor of claim 19 wherein the surface feature is selected from a group consisting of a trench, a region with a first surface tension formed in a substrate having an overall second surface tension, and a region of a first material formed in a substrate made from an overall second material.

21. The transistor of claim 19 further comprising:
an insulator layer overlying the substrate made from a material selected from a group consisting of oxides, nitrides, and ceramics.

22. The transistor of claim 19 further comprising:
an insulator layer overlying the substrate made from a material selected from a group consisting of an oxide and a nitride, and including a first material; and,
wherein the crystallized stripes include the first material.

23. The transistor of claim 15 wherein the crystallized stripes have a structure selected from a group consisting of single-crystal and polycrystalline.

24. The transistor of claim 15 wherein the crystallized stripes are a material selected from a group consisting of Si, Ge, and SiGe.

25. The transistor of claim 15 wherein the transistor active semiconductor region includes a channel region formed from the plurality of oriented crystalline semiconductor stripes.

26. The transistor of claim 15 wherein the transistor active semiconductor region includes source, drain, and channel regions formed from the plurality of oriented crystalline semiconductor stripes.
